(19) United States
(12) Patent Application Publication
(10) Pub. No.: US 2024/0088110 A1
(43) Pub. Date: Mar. 14, 2024

(54) POWER CONVERTER WITH AT LEAST TWO POWER SEMICONDUCTOR MODULES

(71) Applicant: SIEMENS AKTIENGESELLSCHAFT, München (DE)

(72) Inventors: Felix ZEYSS, Erlangen (DE); Philipp KNEISSL, Nürnberg (DE); Jens SCHMENGER, Forchheim (DE)

(73) Assignee: Siemens Aktiengesellschaft, München (DE)

(21) Appl. No.: 18/272,755

(22) PCT Filed: Dec. 1, 2021
(86) PCT No.: PCT/EP2021/083712

§ 371 Date: Jul. 17, 2023

(30) Foreign Application Priority Data
Jan. 18, 2021 (EP) 21152055.6

(51) Int. Cl. H01L 25/11; H01L 23/50; H01L 25/00

(52) U.S. Cl. CPC H01L 25/115; H01L 23/50; H01L 25/50; H02M 7/003

(57) ABSTRACT

A power converter includes at least two power semiconductor modules. Each of the power semiconductor modules includes at least one power semiconductor and power contacts, which are electrically conductively connected to the power semiconductors via an external circuit for the parallel connection of the power semiconductor modules. The power semiconductors are further connected to one another in parallel by way of at least one additional connection having a lower parasitic inductance and/or a lower series resistance than the external circuit.

The invention relates to a power converter with at least two, in particular identical, power semiconductor modules.

The Invention further relates to a method for the production of a power converter with at least two, in particular identical, power semiconductor modules.

The power semiconductor modules in such a power converter are for example connected in parallel in order to achieve a higher load current. A power converter should for example be understood as a power rectifier, a power inverter, a converter or a d.c.-d.c. converter. In particular, when power semiconductor modules are connected in parallel, parasitic inductances and resistances can result in an uneven, in particular asymmetrical, power distribution between the power semiconductor modules, which for example excite oscillations and thus can create additional power loss and/or noise radiation. Noise radiation can affect other elements of the power converter and cause spontaneous destruction of a power semiconductor module. Furthermore, an asymmetrical power distribution such as this can mean that the individual power semiconductor modules are subjected to different stresses and the service life for individual modules is reduced.

Against this backdrop, the object of the present invention is to specify a power converter which exhibits greater reliability in comparison with the prior art.

The object is inventively achieved by a power converter with at least two, in particular identical, power semiconductor modules, the power semiconductor modules each having at least one power semiconductor and power contacts, the power semiconductors being electrically conductively connected to the power contacts of the corresponding power semiconductor module, the power contacts being electrically conductively connected in each case via an external circuit for the parallel connection of the power semiconductor modules, the power semiconductors being electrically conductively connected to one another via at least one additional connection means, the at least one additional connection means having a lower parasitic inductance and/or a lower series resistance than the external circuit.

In addition, the object is inventively achieved by a method for the production of a power converter with at least two, in particular identical, power semiconductor modules, the power semiconductor modules in each case having at least one power semiconductor and power contacts, the power semiconductors being electrically conductively connected to the power contacts of the corresponding power semiconductor module, the power contacts being electrically conductively connected in each case via an external circuit for the parallel connection of the power semiconductor modules, the power semiconductors being electrically conductively connected to one another via at least one additional connection means, the at least one additional connection means having a lower parasitic inductance and/or a lower series resistance than the external circuit.

The advantages and preferred configurations set out below in respect of the power converter can be analogously transferred to the production process.

The Invention is based on the consideration of increasing the reliability of a power converter by improving the symmetry in the power distribution between power semiconductor modules connected in parallel. The power semiconductor modules each have at least one power semiconductor and power contacts, the power semiconductors being electrically conductively connected to the power contacts of the corresponding power semiconductor module. For example, the power semiconductors are in each case embodied as a transistor, in particular as an insulated gate bipolar transistor (IGBT), as a metal-oxide semiconductor field-effect transistor (MOSFET), as a field-effect transistor, as a thyristor or as another semiconductor. For example, at least one transistor is assigned a diode, in particular an antiparallel diode. The power contacts, which for example are in each case connected to a collector and/or emitter of at least one IGBT, are in each case electrically conductively connected via an external circuit for the parallel connection of the power semiconductor modules. For example, the external circuit comprises copper bars and/or cables, in particular insulated copper cables for the parallel connection of the power semiconductor modules.

Furthermore, the power semiconductors are electrically conductively connected to one another via at least one additional connection means, the at least one additional connection means having a lower parasitic inductance and/or a lower series resistance than the external circuit. Thanks to the at least one additional connection means the modules connected in parallel are directly connected to one another, so that equalizing currents are able to flow. These equalizing currents prevent the oscillation of the parallel connection and ensure a better symmetry in power distribution. The at least one additional connection means for example comprises conductors, in particular conductors running in parallel, which produce a direct connection between the power semiconductor modules. The conductors are for example produced from copper or a copper alloy. In particular thanks to the direct connection the conductors of the at least one connection means are embodied as shorter than the, comparatively long, copper bars and/or cables of the external circuit, so that the at least one connection means has a lower inductance and/or a lower series resistance than the external circuit. Thanks to the better symmetry in the power distribution the reliability of the power converter is improved.

A further form of embodiment provides that the at least one additional connection means has a lower current-carrying capacity than the external circuit. In particular, since a rated current only flows via the at least one additional connection means for a short time, this can be dimensioned with a lower current-carrying capacity and thus as more compact and more inexpensive.

A further form of embodiment provides that the power semiconductor modules each have a housing which contains the respective power contacts, at least one connection means being arranged so as to run through the housing. The housings are for example produced from a plastic, at least one connection means running through the housing, for example by means of a sealed housing leadthrough, thereby guaranteeing adherence to the air gaps and creepage distances. Thanks to the reduced distance of the housing leadthrough a lower inductance of the at least one connection means is enabled.

A further form of embodiment provides that at least one connection means has connection elements which are integrated into the respective housing and are electrically conductively connected via at least one separate contact element. The, for example identically embodied, connection elements are integrated into the housing for example by means of an, in particular sealed, housing leadthrough. The separate contact element simply and inexpensively produces an electrically conductive connection between the connection elements.

A further form of embodiment provides that a connection element is detachably connected to a contact element. A detachable connection is produced for example by means of a tongue and groove connection. Thanks to such a detachable connection it becomes easier to replace a power semiconductor module, for example in the event of a defect.

A further form of embodiment provides that a connection element is connected to a contact element via a plug-in connection. Such a plug-in connection is for example embodied as a plug-socket connection, wherein for example the connection element has a socket and the contact element has an associated plug. Such an, in particular detachable, plug-in connection is simple, inexpensive and reliable.

A further form of embodiment provides that a connection means comprises a first plug-in element, which is integrated into a first housing, and a second plug-in element, which is integrated into a second housing and differs from the first plug-in element, the first plug-in element and the second plug-in element being electrically conductively connected, in particular detachably, via a plug-in connection. The plug-in elements are for example detachably connected to one another via a plug-socket connection. Thanks to such a connection technique, multiple power semiconductor modules can very easily be connected to one another.

A further form of embodiment provides that a connection means comprises conductors running in parallel. Thanks to conductors running in parallel a capacitance is formed which at least partially compensates for a parasitic inductance of the conductors. The capacitance between the conductors can be flexibly dimensioned for example by the spacing and overlap of the conductors.

A further form of embodiment provides that thanks to the conductors running in parallel a filter, in particular an RC filter, is formed, the limit frequency of which lies in the MHz range. In particular, the capacitance of the RC filter is formed by the conductors running in parallel, and the resistance of the RC filter by the series resistance of the conductors. In particular, the limit frequency of the lowpass filter formed lies above an operating frequency of the power converter, so that higher frequencies are suppressed by the filter effect of the RC filter, this having a positive effect on the oscillation behavior of the power converter.

A further form of embodiment provides that a connection means comprises at least one filter element. Such a filter element is for example a discrete component, in particular a resistor, a capacitor or an RC element. Thanks to such a WO 2022/152453 PCT/EP20211083712 filter element a lower limit frequency is enabled in a space-saving manner, so that oscillations between the power semiconductor modules are damped in a space-saving manner.

A further form of embodiment provides that the at least one additional connection means comprises a PTC thermistor. The PTC thermistor for example contains platinum and/or Resistherm (NiFe30). Thanks to such a PTC thermistor, the resistance of which increases as the temperature rises, equalization currents can flow, primarily in the case of transient events. Furthermore, the at least one additional connection means is protected against overload.

The invention is described and explained in greater detail below on the basis of the exemplary embodiments represented in the figures.

In the drawing:

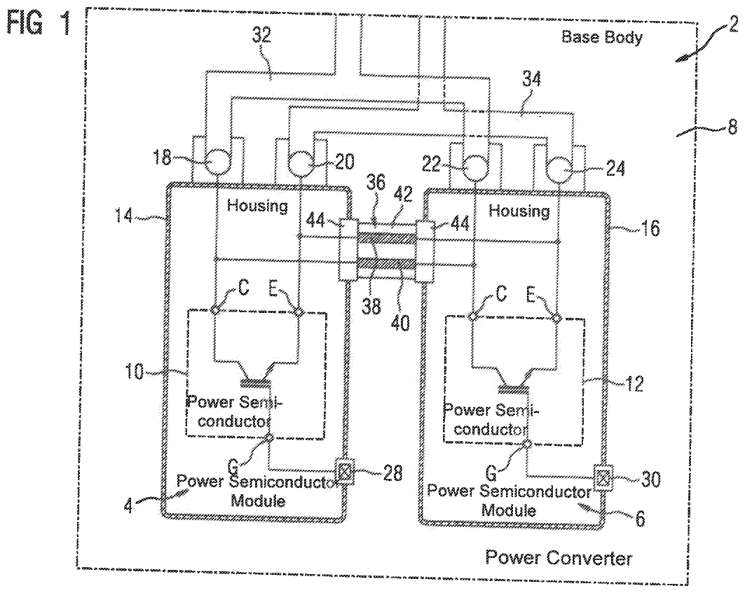

FIG. 1 shows a schematic representation of a first embodiment of a power converter in cross-section,

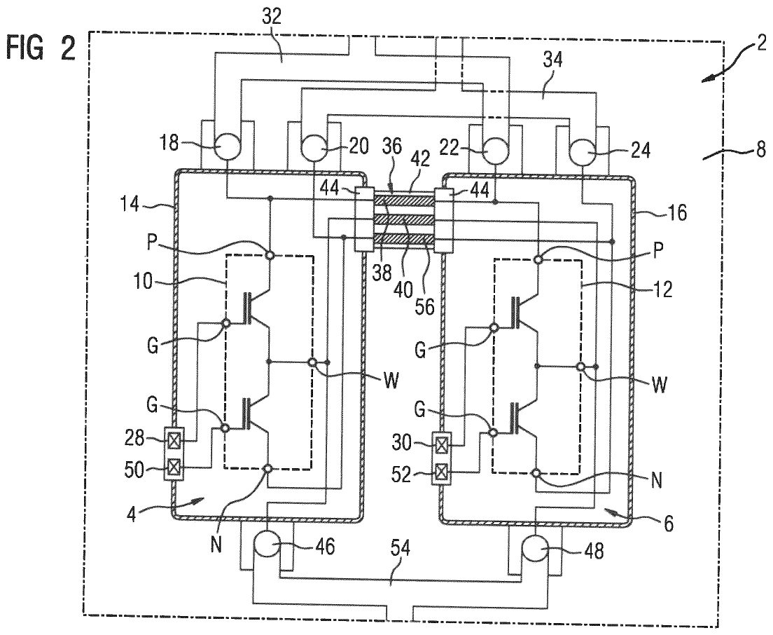

FIG. 2 shows a schematic representation of a second embodiment of a power converter in cross-section,

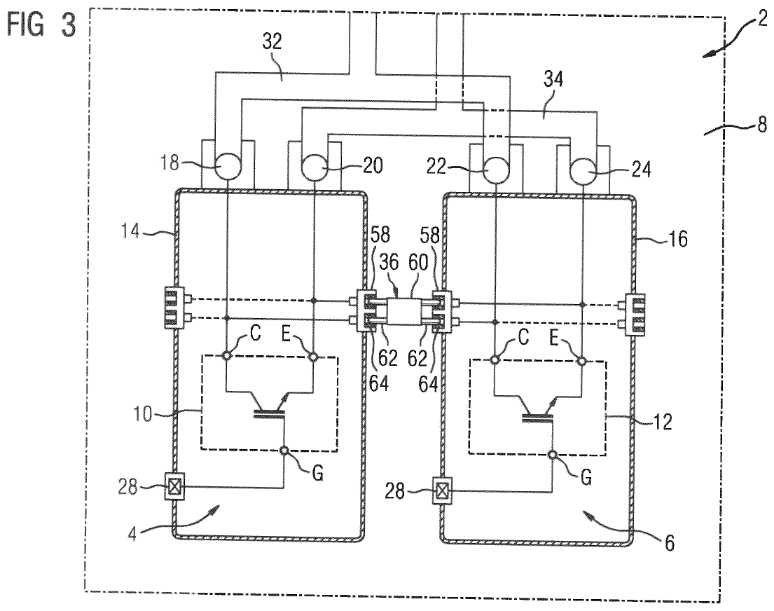

FIG. 3 shows a schematic representation of a third embodiment of a power converter in cross-section,

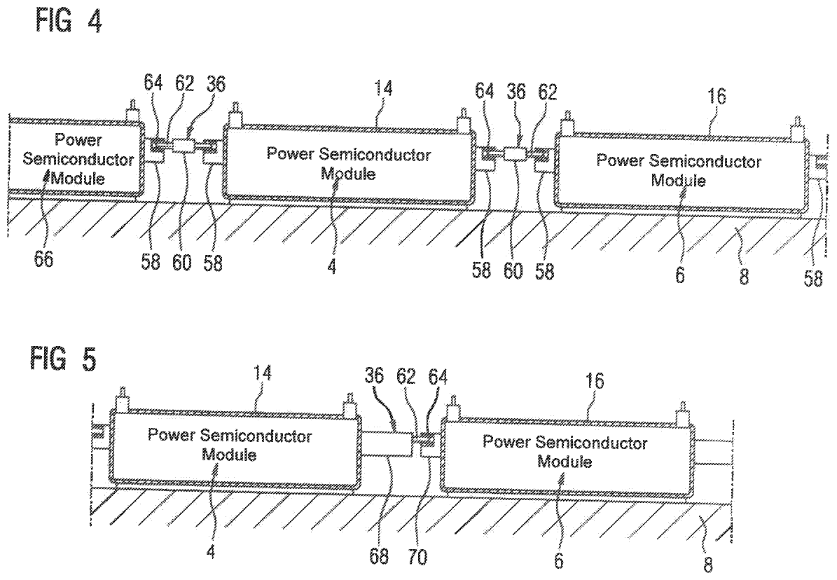

FIG. 4 shows a schematic representation of a fourth embodiment of a power converter in cross-section,

FIG. 5 shows a schematic representation of a fifth embodiment of a power converter in cross-section and

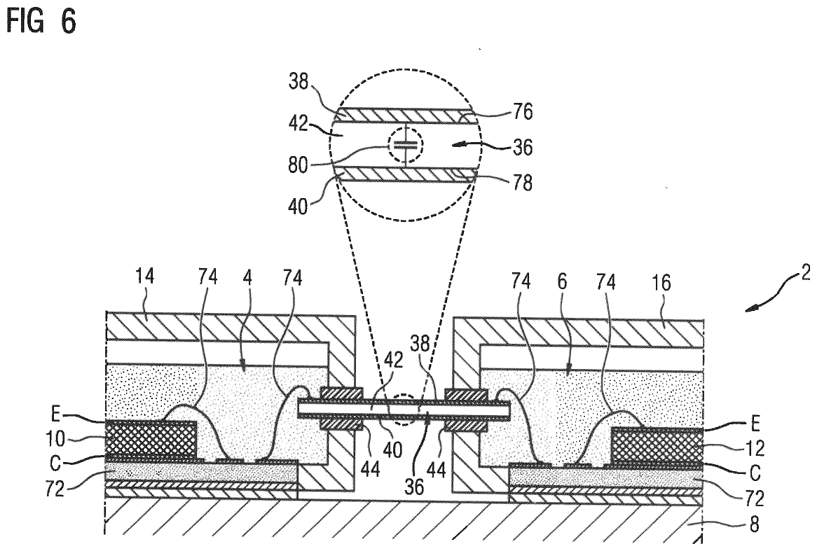

FIG. 6 shows a schematic representation of a sixth embodiment of a power converter in cross-section.

The exemplary embodiments explained below are preferred forms of embodiment of the invention. In the exemplary embodiments the components described of the forms of embodiment each represent individual features of the invention, to be considered independently of one another, which each develop the invention independently of one another and thus are to be regarded also individually or in a combination of components other than the one shown as a component of the invention. Furthermore, the forms of embodiment described can also be supplemented by further of the features of the invention already described.

The same reference characters have the same meaning in the various figures.

FIG. 1 shows a schematic representation of a first embodiment of a power converter 2 in cross-section, which has two identical power semiconductor modules 4, 6. The power semiconductor modules 4, 6 are arranged on a common base body 8, which is embodied for example as a heat sink manufactured from aluminum or an aluminum alloy, and each have a power semiconductor 10, 12 which by way of example is embodied as an insulated gate bipolar transistor (IGBT). Alternatively, the power semiconductors 10, 12 are embodied as a metal-oxide semiconductor field-effect transistor (MOSFET), as a field-effect transistor, as a thyristor, or as a diode. In particular, the power semiconductors 10, 12 embodied as an IGBT are each assigned an antiparallel diode, which is not represented in FIG. 1 for reasons of clarity. Furthermore, the power semiconductors 10, 12 embodied as an IGBT each have a collector contact C, an emitter contact E and a gate contact G.

In addition, the power semiconductor modules 4, 6 each have a housing 14, 16, which are produced for example from a plastic and contain power contacts 18, 20, 22, 24. In this case a first power semiconductor 10 is arranged in a first housing 14, which contains a first power contact 18 and a second power contact 20, while a second power semiconductor 12 is arranged in a second housing 16, which contains a third power contact 22 and a fourth power contact 24. The collector contact C of the first power semiconductor 10 is connected to the first power contact 18, while the emitter contact E of the first power semiconductor 10 is connected to the second power contact 20. Analogously, the collector contact C of the second power semiconductor 12 is connected to the third power contact 18, while the emitter contact E of the second power semiconductor 12 is connected to the fourth power contact 24. Additionally, the housings 14, 16 of the power semiconductor modules 4, 6 each have a control contact 28, 30, the gate contact G of the first power semiconductor 10 being connected to a first control contact 28 and the gate contact G of the second power semiconductor 12 being connected to a second control contact 30. For the parallel connection of the power semiconductors 10, 12 the corresponding power contacts 18, 20, 22, 24 are each electrically conductively connected via an external circuit 32, 34. In particular, the collector contacts C of the power semiconductors 10, 12 are electrically conductively connected by a first external circuit 32 and the emitter contacts E of the power semiconductors 10, 12 by a second external circuit 34. The external circuit 32, 34 for example in each case comprises at least one copper bar. Additionally or alternatively, the external circuit 32, 34 can have cables, in particular insulated copper cables.

In addition, the power semiconductors 10, 12 are directly electrically conductively connected to one another via an additional connection means 36. The additional connection means 36 comprises conductors 38, 40, in particular running in parallel, which produce a direct connection between the power semiconductor modules 4, 6, the emitter contact E of the first power semiconductor 10 being connected to the emitter contact E of the second power semiconductor 12 via a first conductor 38 and the collector contact C of the first power semiconductor 12 being connected to the collector contact C of the second power semiconductor 12 via a second conductor 40. The conductors 38, 40 are for example produced from copper or a copper alloy and are applied as metallization on a dielectric, in particular ceramic, substrate 42. The additional connection means 36 has a lower parasitic inductance and/or a lower series resistance than the external circuit 32, 34, since in particular the short conductors 38, 40 of the connection means 36 have a lower inductance and/or a lower series resistance than the, comparatively long, copper bars and/or cables of the external circuit 32, 34. Thanks to such a direct connection between the power semiconductor modules 4, 6, equalizing currents can flow between the power semiconductors 10, 12, which prevent an oscillation of the parallel connection and ensure better symmetry in the power distribution. In particular, the connection means 36 is arranged to run through the housings 14, 16, wherein gaskets 44 seal the respective housing 14, 16 in the region of the housing leadthrough.

Thanks to the conductors 38, 40 running in parallel, a filter, in particular an RC filter, can be formed, the limit frequency of which lies above an operating frequency of the power converter 2. For example, the limit frequency of the filter formed by the conductors 38, 40 running in parallel lies in the MHz range. The connection means 36 can comprise at least one, in particular discrete, filter element, for example a resistor, a capacitor and/or an RC element. Oscillations between the power semiconductor modules 4, 6 are damped by such a filter. Additionally or alternatively, the connection means can comprise a PTC thermistor, such as platinum or Resistherm (NiFe30). In particular, at least one of the conductors 38, 40 is produced from a PTC thermistor. Thanks to such a PTC thermistor, the resistance of which increases as the temperature rises, equalization currents can flow, primarily in the case of transient events. Furthermore, the connection means 36 is protected against overload.

FIG. 2 shows a schematic representation of a second embodiment of a power converter 2 in cross-section, the power semiconductors 10, 12 being in each case embodied as a half-bridge. A half-bridge, which is constructed from two stacked IGBTs, comprises a positive voltage supply contact P, a negative voltage supply contact N, an alternating voltage contact W and two gate contacts G. The positive voltage supply contact P of the first power semiconductor 10 is connected to the first power contact 18, while the negative voltage supply contact N of the first power semiconductor 10 is connected to the second power contact 20. Analogously, the positive voltage supply contact P of the second power semiconductor 12 is connected to the third power contact 22, while the negative voltage supply contact N of the second power semiconductor 12 is connected to the fourth power contact 24. Furthermore, the alternating voltage contact W of the first power semiconductor 10 is connected to a fifth power contact 46 and the alternating voltage contact W of the second power semiconductor 12 to a sixth power contact 48. The gate contacts G of the first power semiconductor 10 and of the second power semiconductor 12 are in each case connected to a control contact 28, 30, 50, 52.

For the parallel connection of the power semiconductors 10, 12 the corresponding power contacts 18, 20, 22, 24, 46, 48 are each electrically conductively connected via an external circuit 32, 34, 54. In particular, the positive voltage supply contacts P of the power semiconductors 10, 12 are electrically conductively connected by a first external circuit 32, the negative voltage supply contacts N of the power semiconductors 10, 12 by a second external circuit 34 and the alternating voltage contacts W of the power semiconductors 10, 12 by a third external circuit 54. The external circuit 32, 34, 54 for example comprises in each case at least one copper bar. Additionally or alternatively, the external circuit 32, 34, 54 can comprise cables, in particular insulated copper cables.

In addition, the power semiconductors 10, 12 are directly electrically conductively connected to one another via an additional connection means 36. The additional connection means 36 comprises, in particular parallel-running, conductors 38, 40, 56 which produce a direct connection between the power semiconductor modules 4, 6, the positive voltage supply contact P of the first power semiconductor 10 being connected to the positive voltage supply contact P of the second power semiconductor 12 via a first conductor 38, the negative voltage supply contact N of the first power semiconductor 12 to the negative voltage supply contact N of the second power semiconductor 12 via a second conductor 40 and the alternating voltage contact W of the first power semiconductor 10 to the alternating voltage contact W of the second power semiconductor 12 via a third conductor 56. The further embodiment of the power converter 2 in FIG. 2 corresponds to that in FIG. 1.

FIG. 3 shows a schematic representation of a third embodiment of a power converter 2 in cross-section, the connection means 36 having, in particular identical, connection elements 58 integrated into the respective housings 14, 16, which are electrically conductively connected via an, in particular axisymmetric, separate contact element 60. The contact element 60 is detachably connected on both sides via a plug-in connection to the connection elements 58 integrated into the housings 14, 16. The plug-in connection is embodied as a plug-socket connection, the contact element 60 by way of example having plugs 62, which are plugged into appropriate sockets 64 of the connection elements 58. The further embodiment of the power converter 2 in FIG. 3 corresponds to that in FIG. 1.

FIG. 4 shows a schematic representation of a fourth embodiment of a power converter 2 in cross-section, which by way of example has three identical power semiconductor modules 4, 6, 66. The power semiconductor modules 4, 6, 66 each have a power semiconductor, which is not represented in FIG. 4 for reasons of clarity, the power semiconductors, as shown in FIG. 3, being connected in parallel via an external circuit. In addition, the power semiconductors of the power semiconductor modules 4, 6, 66 are directly electrically conductively connected to one another via additional connection means 36. The further embodiment of the power converter 2 in FIG. 4 corresponds to that in FIG. 3.

FIG. 5 shows a schematic representation of a fifth embodiment of a power converter 2 in cross-section. The connection means 36 has a first plug-in element 68, which is integrated into the first housing 14, and a second plug-in element 70, which is integrated Into the second housing 16 and differs from the first plug-in element 68. By way of example, the first plug-in element 68 has a plug 62 and the second plug-in element 70 has a socket 64 matching the plug 62. The first plug-In element 68 and the second plug-in element 70 are connected, in particular detachably, via a plug-in connection. The further embodiment of the power converter 2 in FIG. 5 corresponds to that in FIG. 3.

FIG. 6 shows a schematic representation of a sixth embodiment of a power converter 2 in cross-section, which has two power semiconductor modules 4, 6 with power semiconductors 10, 12 connected in parallel. The power semiconductors 10, 12 embodied as IGBTs are connected in a materially bonded manner to a DCB substrate 72 via the collector C, for example by soldering or sintering, the emitter E being contacted via a bond connection 74. The connection means 36, which directly electrically conductively connects the power semiconductors 10, 12 to one another, is likewise connected to the DCB substrate 72 via a bond connection 74. Furthermore, the connection means 36 has a first conductor 38, which is attached to a first side 76 of a dielectric, in particular ceramic, substrate 42. In addition, the connection means 36 has a second conductor 40, which is attached to a second side 78, opposite the first side 76, of the dielectric, in particular ceramic, substrate 42, so that the conductors 38, 40 are arranged in parallel on opposite sides of the substrate 42 and an, in particular parasitic, capacitor 80 is formed by the conductors 38, 40 running in parallel. In particular, the capacitor 80 is part of a filter, in particular an RC filter, the limit frequency of which lies above an operating frequency of the power converter 2. Contacting of the second conductor 40 of the connection means 36 takes place for example from the DCB substrate 72 via a bond connection 74 to the first side 76 of the connection means 36, the second conductor 40 being guided, in particular inside the respective housing 14, 16, for example via a through contact, to the second side 78 of the connection means 36. The further embodiment of the power converter 2 in FIG. 6 corresponds to that in FIG. 1.

In summary, the invention relates to a power converter 2 with at least two, in particular identical, power semiconductor modules 4, 6. In order to achieve greater reliability in comparison with the prior art, it is proposed that the power semiconductor modules 4, 6 each have at least one power semiconductor 10, 12 and power contacts 18, 20, 22, 24, 46, 48, the power semiconductors 10, 12 being electrically conductively connected to the power contacts 18, 20, 22, 24, 46, 48 of the corresponding power semiconductor module 4, 6, the power contacts 18, 20, 22, 24, 46, 48 being in each case electrically conductively connected via an external circuit 32, 34, 54 for the parallel connection of the power semiconductor modules 4, 6, the power semiconductors 10, 12 being electrically conductively connected to one another via at least one additional connection means 36, the at least one additional connection means 36 having a lower parasitic inductance and/or a lower series resistance than the external circuit 32, 34, 54.

1.-15. (canceled)

16. A power converter, comprising:
at least two power semiconductor modules, each of the at least two power semiconductor modules including a power semiconductor and power contacts which are electrically conductively connected to the power semiconductors via an external circuit for a parallel connection of the at least two power semiconductor modules; and
an additional connection having a lower parasitic inductance or a lower series resistance, or both, than the external circuit and electrically conductively connecting the power semiconductors of the at least two power semiconductor modules to one another.

17. The power converter of claim 16, wherein the at least two power semiconductor modules are identical.

18. The power converter of claim 16, wherein the additional connection has a current-carrying capacity which is lower than a current-carrying capacity of the external circuit.

19. The power converter of claim 16, wherein each of the at least two power semiconductor modules includes a housing containing respective ones of the power contacts, said additional connection being arranged so as to extend through the housing.

20. The power converter of claim 19, wherein the additional connection includes connection elements that are integrated into the housing of each of the at least two power semiconductor modules, respectively, said connection elements being electrically conductively connected to one another via a separate contact element.

21. The power converter of claim 20, wherein the connection elements are detachably connected to the separate contact element.

22. The power converter of claim 20, wherein the connection elements are connected to the separate contact element via a plug-In connection.

23. The power converter of claim 19, wherein the additional connection comprises a first plug-in element integrated into the housing of one of the at least two power semiconductor modules, and a second plug-in element which is different from the first plug-in element and integrated into the housing of the other one of the at least two power semiconductor modules, said second plug-in element electrically conductively connected to the first plug-in element via a plug-in connection.

24. The power converter of claim 23, wherein the second plug-in element is detachably connected to the first plug-in element via the plug-in connection.

25. The power converter of claim 16, wherein the additional connection comprises conductors running in parallel.

26. The power converter of claim 25, wherein the conductors running in parallel form a filter having a limit frequency in a MHz range.

27. The power converter of claim 26, wherein the fitter is an RC filter.

28. The power converter of claim 16, wherein the additional connection comprises a filter element.

29. The power converter of claim 16, wherein the additional connection comprises a PTC thermistor.

30. A method for producing a power converter comprising at least two power semiconductor modules, each of the at least two power semiconductor modules including a power semiconductor and power contacts, the method comprising:
electrically conductively connecting the power semiconductors to the power contacts of the corresponding one of the at least two power semiconductor modules;
electrically conductively connecting the power contacts of the at least two power semiconductor modules in parallel via an external circuit; and
electrically conductively connecting the power semiconductors to one another via an additional connection having a lower parasitic inductance or a lower series resistance, or both, than the external circuit.

31. The method of claim 30, further comprising:
installing each of the at least two power semiconductor modules in a corresponding housing that comprises the power contacts; and
arranging the additional connection so as to run through the housing of each of the at least two power semiconductor modules.

32. The method of claim 30, further comprising:
integrating connection elements of the additional connection into the housing of each of the at least two power semiconductor modules, and
electrically conductively connecting the connection elements via a separate contact element.

33. The method of claim 32, wherein the connection elements are detachably connected.

34. The method of claim 31, further comprising:
integrating a first plug-in element of the additional connection into the housing of one of the at least two power semiconductor modules;
integrating a second plug-in element of the additional connection into the housing of the other one of the at least two power semiconductor modules, with the second plug-in element being different from the first plug-in element; and
electrically conductively connecting the second plug-in element to the first plug-in element via a plug-in connection.

35. The method of claim 34, further comprising detachably connecting the first plug-in element and the second plug-in element via the plug-in connection.
